(19) United States
(12) Patent Application Publication
(10) Pub. No.: US 2026/0166756 A1
(43) Pub. Date: Jun. 18, 2026

(54) VACUUM PAD, HAND, AND TRANSFER APPARATUS

(71) Applicant: SEMES CO., LTD., Cheonan-si (KR)

(72) Inventors: Byung Hyuk KANG, Incheon (KR); Tae Won YUN, Namwon-si (KR); Seong Hyeon BAEK, Dangjin-si (KR); Jun Chel LEE, Suwon-si (KR)

(21) Appl. No.: 19/386,297

(22) Filed: Nov. 12, 2025

(30) Foreign Application Priority Data
Dec. 16, 2024 (KR) 10-2024-0186877

(51) Int. Cl. B25J 15/06; B25J 11/00; B25J 13/08; F16K 31/00; G05D 16/20; H01L 21/683

(52) U.S. Cl. CPC B25J 15/0625; B25J 13/087; F16K 31/005; G05D 16/2022; B25J 11/0095; H10P 72/78

(57) ABSTRACT

A vacuum pad, a hand, and a transfer apparatus are provided. The vacuum pad includes a piezoelectric element installed on a hand body while covering a suction hole of the hand body, and having a hollow portion, and a pad member installed on the piezoelectric element to cover the hollow portion, and having a pad hole communicating with the suction hole.

### CROSS-REFERENCE TO RELATED APPLICATIONS

This application claims benefit of priority to Korean Patent Application No. 10-2024-0186877 filed on Dec. 16, 2024 in the Korean Intellectual Property Office, the disclosure of which is incorporated herein by reference in its entirety.

### BACKGROUND

### 1. Field

The present disclosure relates to a vacuum pad, a hand, and a transfer apparatus for vacuum-absorbing a substrate.

### 2. Description of Related Art

In a substrate processing device, a transfer apparatus transports substrates. This transfer apparatus utilizes a robotic arm equipped with a hand.

The substrate is placed on the hand, and a vacuum pad is installed on the hand to securely hold the substrate in place.

However, while substrates with low warpage are smoothly vacuum-absorbed by the vacuum pad, substrates with large warpage frequently fail to vacuum-absorb.

### SUMMARY

An aspect of the present disclosure is to provide a vacuum pad, a hand, and a transfer apparatus, which may firmly vacuum-absorb even a greatly warped substrate.

According to an aspect of the present disclosure, a vacuum pad includes a piezoelectric element installed on a hand body while covering a suction hole of the hand body, and having a hollow portion; and a pad member installed on the piezoelectric element to cover the hollow portion, and having a pad hole communicating with the suction hole.

The pad member may have a donut shape in which the pad hole is formed, and may have an outer side portion into which an inner edge of the hollow portion of the piezoelectric element is inserted.

The pad member may be inserted into the hollow portion, and an upper end of a side portion of the pad member may be provided with a protruding protrusion formed thereon to be caught on an upper edge of the hollow portion. The vacuum pad may further include an O-ring installed on a side portion of the pad member to maintain an airtight seal between the pad member and an inner edge of the hollow portion of the piezoelectric element.

The pad member may be disposed over a perimeter of the hollow portion of the piezoelectric element, and the vacuum pad may further include a first elastic member connecting the pad member and the piezoelectric element between the pad member and the piezoelectric element. The first elastic member may have a first displacement-absorbing groove formed therein to absorb mechanical displacement of the pad member and the piezoelectric element.

The piezoelectric element may be disposed around a perimeter of the suction hole of the hand body, and the vacuum pad may further include a second elastic member connecting the piezoelectric element and the hand body between the piezoelectric element and the hand body. The second elastic member may have a second displacement-absorbing groove formed therein to absorb mechanical displacement of the piezoelectric element.

The piezoelectric element may include a first electrode and a second electrode to which voltages of opposite polarities are applied, and the first electrode or the second electrode may be connected to ground.

The piezoelectric element may be a bimorph piezoelectric element.

According to an aspect of the present disclosure, a hand of a transfer apparatus includes a hand body having a suction channel in which a suction hole is formed; and a vacuum pad installed in the suction hole and vacuum-absorbing a substrate. The vacuum pad includes a piezoelectric element installed on the hand body to cover the suction hole and having a hollow portion; and a pad member installed in the hollow portion of the piezoelectric element and having a pad hole communicating with the suction hole.

According to an aspect of the present disclosure, a transfer apparatus includes a robot arm; a hand installed on the robot arm and on which a substrate is mounted; and a warpage measurement sensor measuring a warpage shape of the substrate and a controller electrically connected to the warpage measurement sensor. The hand includes a hand body installed on the robot arm and having a suction channel with a suction hole formed therein; and a vacuum pad installed in the suction hole and vacuum-absorbing the substrate. The vacuum pad includes a piezoelectric element installed on the hand body to cover the suction hole and having a hollow portion; and a pad member installed in the hollow portion of the piezoelectric element and having a pad hole communicating with the suction hole. The piezoelectric element is a bimorph piezoelectric element, and the controller controls a voltage applied to the piezoelectric element according to a warpage shape of the substrate measured by the warpage measurement sensor.

### BRIEF DESCRIPTION OF DRAWINGS

The above and other aspects, features, and advantages of the present disclosure will be more clearly understood from the following detailed description, taken in conjunction with the accompanying drawings, in which:

FIGS. 1 and 2 are drawings illustrating a warped substrate not being vacuum-attached to the vacuum pad of a hand of a transfer apparatus according to the related art;

FIG. 3 is a drawing illustrating a transfer apparatus according to a first embodiment;

FIG. 4 is a drawing illustrating a hand of the transfer apparatus of FIG. 3;

FIG. 5 and FIG. 6 are drawings illustrating piezoelectric elements bending in opposite directions when voltages are applied in opposite directions to the vacuum pad of the hand of FIG. 4;

FIG. 7 and FIG. 8 are drawings illustrating various types of warped substrates being vacuum-attached to the vacuum pad of the hand of FIG. 5;

FIG. 9 is a drawing illustrating a hand of a transfer apparatus according to a second embodiment;

FIG. 10 is a drawing illustrating a hand of a transfer apparatus according to a third embodiment;

FIG. 11 is a drawing illustrating a hand of a transfer apparatus according to a fourth embodiment; and

FIG. 12 is a drawing illustrating an antistatic structure of a vacuum pad in the present disclosure.

### DETAILED DESCRIPTION

Hereinafter, with reference to the attached drawings, example embodiments will be described in detail so that those skilled in the art may easily practice the present disclosure. However, in describing example embodiments in detail, if a detailed description of related known functions or configurations is deemed to unnecessarily obscure the gist of the present disclosure, such detailed descriptions will be omitted. Furthermore, the same reference numerals are used throughout the drawings for components with similar functions and actions. Furthermore, in this specification, terms such as “on,” “upper part,” “top surface,” “below,” “lower part,” “lower side,” “lower surface,” “side surface,” and the like are based on the drawings and may vary depending on the direction in which the components are disposed.

In addition, throughout the specification, when a part is referred to as being “connected” to another part, this includes not only cases where it is “directly connected,” but also cases where it is “indirectly connected” with another component therebetween. Furthermore, unless otherwise stated, “including” a component does not exclude other components but rather implies the inclusion of other components.

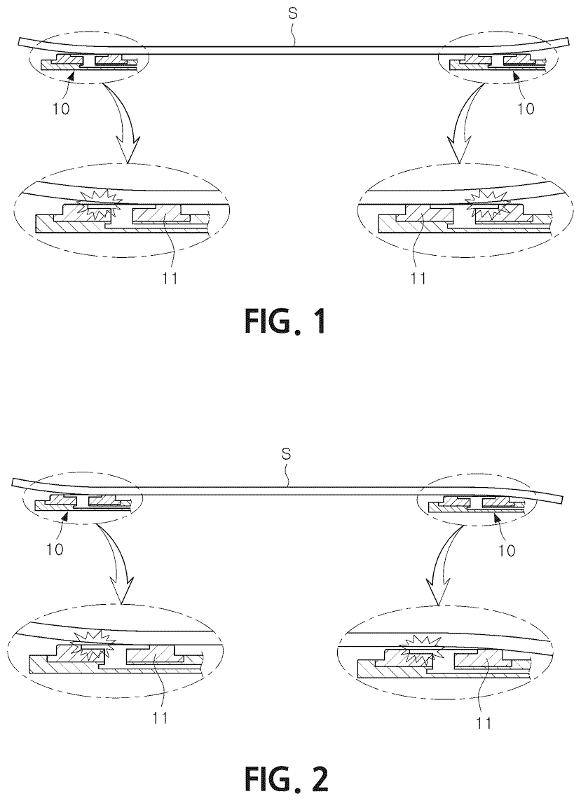

FIGS. 1 and 2 illustrate a warped substrate not being vacuum-attached to the vacuum pad of a hand of a transfer apparatus of the related art.

Referring to the drawings, a hand 10 of the transfer apparatus of the related art secures a placed substrate S using vacuum suction.

For example, the hand 10 includes a vacuum pad 11, and the substrate S is attached to the vacuum pad 11 by air suction through the vacuum pad 11.

However, while substrates with low warpage are smoothly vacuum-attached to the vacuum pad 11, substrates with large warpage frequently fail to vacuum-attach.

For example, as illustrated in FIG. 1, the substrate S may be significantly warped, with both sides rising upward. In this case, both sides of the substrate S may not be completely attached to the vacuum pad 11.

In detail, the left vacuum pad 11 is spaced apart from the substrate S at the left side thereof, and the right vacuum pad 11 is spaced apart from the substrate S at the right side thereof, so that the substrate S is not completely vacuum-attached to the vacuum pad 11.

As another example, as illustrated in FIG. 2, the substrate S may be significantly bent, with the left side rising upward and the right side descending downward. In this case, both sides of the substrate S may not be completely attached to the vacuum pad 11.

In detail, the left vacuum pad 11 is spaced apart from the substrate S at the left side thereof, and the right vacuum pad 11 is spaced apart from the substrate S at the left side thereof, so that the substrate S is not completely vacuum-attached to the vacuum pad 11.

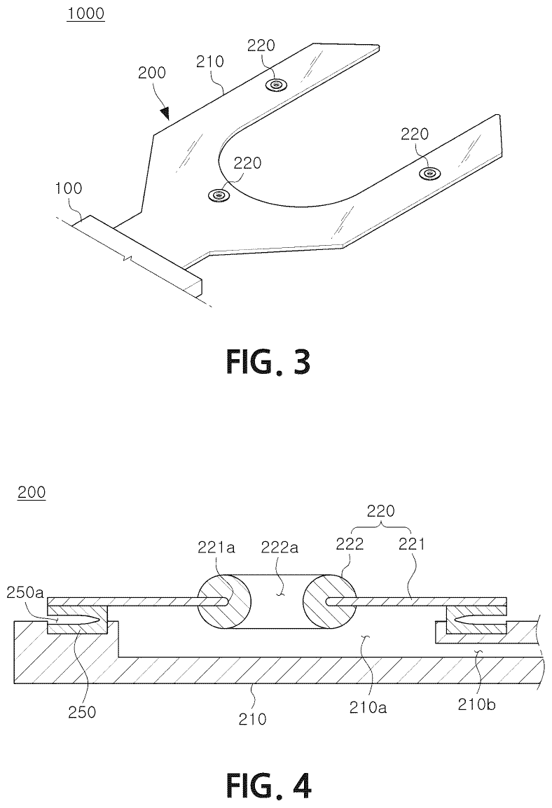

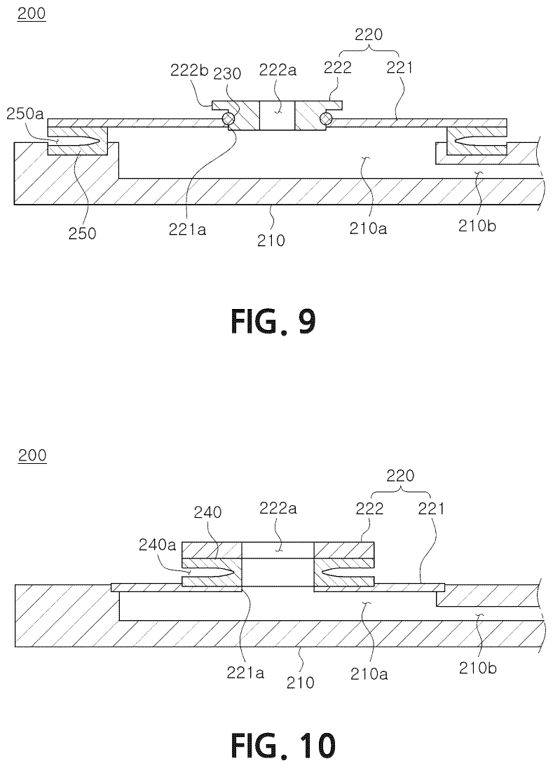

FIGS. 3 to 8 are drawings illustrating a transfer apparatus according to a first embodiment, and FIGS. 9 to 11 are drawings illustrating hands of a transfer apparatus according to second to fourth embodiments.

Referring to the drawings, a transfer apparatus 1000 according to an embodiment of the present disclosure may include a robot arm 100 and a hand 200.

The transfer apparatus 1000 according to an embodiment of the present disclosure functions to transfer substrates in substrate processing equipment. For example, a transfer robot may be utilized.

The transfer apparatus 1000 employing a robot structure as described above includes a robot arm 100.

The robot arm 100 may have a drive structure that smoothly and easily transports the substrate S to the desired transfer location, and thus, the present disclosure does not limit a specific structure thereof.

The hand 200 is installed on the robot arm 100 and has a structure in which the substrate S is fixed, thereby stably and firmly supporting the substrate S.

In detail, the hand 200 may include a hand body 210 and a vacuum pad 220.

The hand body 210 is installed on the robot arm 100 and may have the form of a plate to support the substrate S.

This hand body 210 is formed to have a certain thickness, has a suction channel 210b formed internally, and has a suction hole 210a formed in the upper portion, communicating with the suction channel 210b.

Although not illustrated in the drawing, the suction channel 210b is connected to a vacuum pump and serves as a passage through which air is sucked by the operation of the vacuum pump.

Furthermore, the suction hole 210a is connected to the suction channel 210b and has a structure that opens upwards of the hand body 210, and serves as a passage through which air is sucked together with the suction channel 210b.

The vacuum pad 220 is installed in the suction hole 210a and vacuum-absorbs the substrate S.

In detail, the vacuum pad 220 may include a piezoelectric element 221 and a pad member 222.

The piezoelectric element 221 is installed in the hand body 210 to cover the suction hole 210a, and for example, may be installed on the upper edge of the suction hole 210a while covering the suction hole 210a.

This piezoelectric element 221 has a hollow portion 221a, and the hollow portion 221a communicates with the suction hole 210a of the hand body 210.

The piezoelectric element 221 configured as described above allows the suction hole 210a of the hand body 210 to be communicated with the outside through the hollow portion 221a while covering the suction hole 210a of the hand body 210.

Furthermore, the pad member 222 is installed in the hollow portion 221a of the piezoelectric element 221, and for example, may be installed on the upper edge of the suction hole 210a while covering the hollow portion 221a.

This pad member 222 has a pad hole 222a that is in communication with the suction hole 210a.

The pad member 222, configured as described above, covers the hollow portion 221a of the piezoelectric element 221 and allows the suction hole 210a of the hand body 210 to communicate with the outside through the pad hole 222a.

Meanwhile, although not illustrated in the drawings, in the present disclosure, a warpage measurement sensor and a controller may be included.

The warpage measurement sensor is a sensor that measures the warpage shape of a substrate S.

This warpage measurement sensor determines whether the substrate S is warped, with both sides rising or falling, or whether the substrate S is warped, with one side rising and the other side falling.

This warpage measurement sensor only needs to accurately measure the warpage shape of the substrate S. It should be understood that any warpage measurement sensor of the related art may be utilized, and is not limited to the present disclosure.

The controller may also be electrically connected to the warpage measurement sensor.

The controller may control the voltage applied to the piezoelectric element 221 based on the warpage shape of the substrate S measured by the warpage measurement sensor.

Meanwhile, the piezoelectric element 221 in an embodiment of the present disclosure is utilized as a configuration similar to an actuator, and the piezoelectric element 221 as described above may generate mechanical displacement by receiving a voltage.

To this end, the piezoelectric element 221 may be, for example, a bimorph piezoelectric element 221, as illustrated in FIG. 12.

In detail, the bimorph piezoelectric element 221 is a piezoelectric element 221 composed of two unit piezoelectric elements 221′ that operate together, generating a relatively greater mechanical displacement by operating in opposite directions.

For example, the piezoelectric element 221 composed of the bimorph piezoelectric element 221 generates greater bending displacement than that of the piezoelectric element 221 composed of a single unit piezoelectric element 221′, as one unit piezoelectric element 221′ expands and the other unit piezoelectric element 221′ contracts.

In detail, the bimorph piezoelectric element 221 includes two unit piezoelectric elements 221′ and an intermediate electrode disposed therebetween. This intermediate electrode connects the two unit piezoelectric elements 221′ to form an integrated structure.

When voltage is applied to the bimorph piezoelectric element 221, the charges within the piezoelectric element 221 are rearranged, resulting in mechanical deformation.

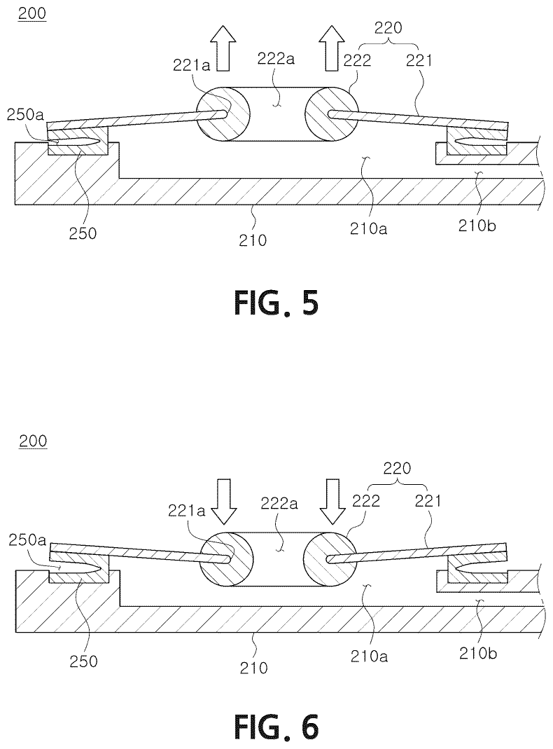

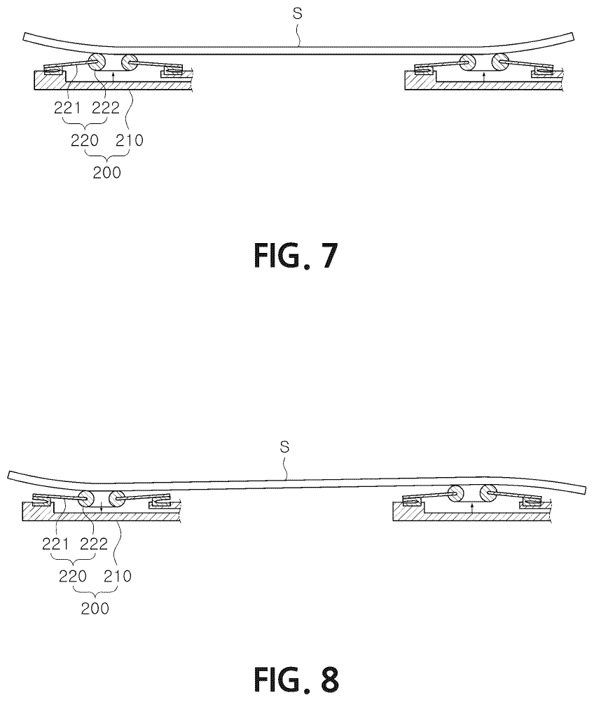

As an example, when a negative voltage is applied to the first electrode E1, the intermediate electrode of the bimorph piezoelectric element 221, to become a negative electrode, and a positive voltage is applied to the second electrode E2, the upper and lower electrodes of the bimorph piezoelectric element 221, to become a positive electrode; the upper unit piezoelectric element 221′ contracts and the lower unit piezoelectric element 221′ expands, so that the bimorph piezoelectric element 221 has a tilted shape with a central portion raised upward, as illustrated in FIG. 5. Due to the mechanical displacement of the bimorph piezoelectric element 221, when the substrate S is raised on both sides, as illustrated in FIG. 7, or when the right side of the substrate S is raised, as illustrated on the right side of FIG. 8, the pad member 222 may support the raised portion of the substrate S.

As another example, when a positive voltage is applied to the first electrode E1, the intermediate electrode of the bimorph piezoelectric element 221, to become a positive electrode, and a negative voltage is applied to the second electrode E2, the upper and lower electrodes of the bimorph piezoelectric element 221, to become a negative electrode; the upper unit piezoelectric element 221′ expands and the lower unit piezoelectric element 221′ contracts, resulting in the bimorph piezoelectric element 221 taking on a tilted shape with a central portion thereof lowered, as illustrated in FIG. 6. Due to the mechanical displacement of the bimorph piezoelectric element 221, when the left side of the substrate S is lowered, as illustrated on the left side of FIG. 8, the pad member 222 may support the lowered portion of the substrate S.

Furthermore, the piezoelectric element 221 in an embodiment of the present disclosure is not limited to being composed of a bimorph piezoelectric element 221, and may also be composed of a single unit piezoelectric element 221′.

Furthermore, the piezoelectric element 221 in an embodiment of the present disclosure may adopt an anti-static structure.

For example, as illustrated in FIG. 12, the piezoelectric element 221 includes a first electrode E1 and a second electrode E2 to which voltages of opposite polarities are applied. Either the first electrode E1 or the second electrode E2 may be connected to ground G.

In detail, in the bimorph piezoelectric element 221, the first electrode E1, the intermediate electrode, or the second electrode E2, the upper and lower electrodes, may be connected to the ground G. For example, the ground G may be a portion of the transfer apparatus 1000 that functions as a ground.

By connecting the first electrode E1 or the second electrode E2 of the piezoelectric element 221 to the ground G, external electrical noise or static electricity may be prevented. This improves the stability of the electrical signal in the present disclosure, thereby maintaining the stable performance of the piezoelectric element 221.

Meanwhile, various embodiments of the vacuum pad 220 in the present disclosure are described below.

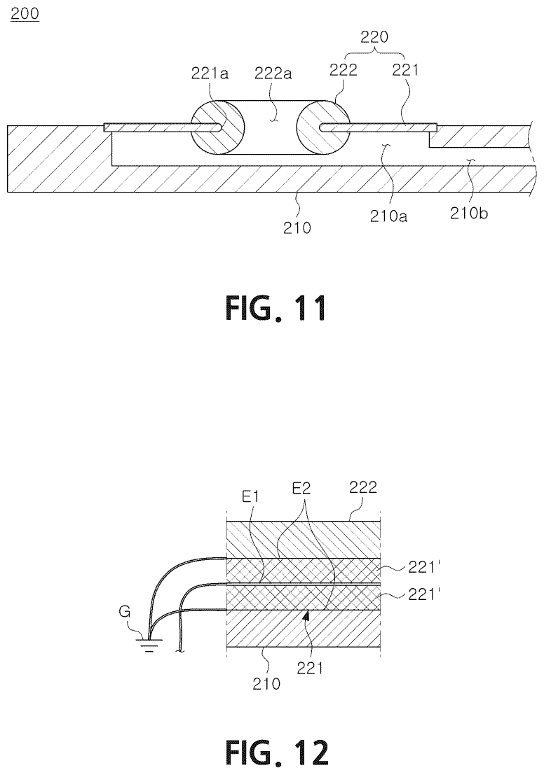

According to the first embodiment illustrated in FIGS. 3 to 8 and the fourth embodiment illustrated in FIG. 11, the pad member 222 of the vacuum pad 220 may be shaped like a donut with a pad hole 222a formed in the center.

For example, the pad member 222 may have a donut shape with the pad hole 222a formed in the center.

One side of the pad member 222 has a circular cross-section, and may thus stably support the substrate S without frictional damage when supporting the substrate.

Furthermore, the pad member 222 may have a structure in an outer side portion thereof, into which an inner edge of the hollow portion 221a of the piezoelectric element 221 is inserted.

This structure, when the piezoelectric element 221 is connected to the donut-shaped pad member 222, may implement a more robust and stable connection structure than a structure in which the piezoelectric element 221 is connected to the outer surface of the pad member 222.

According to the second embodiment illustrated in FIG. 9, the pad member 222 is inserted into the hollow portion 221a, and a protruding protrusion 222b may be formed on the upper end of the side portion of the pad member 222 to be caught on the upper edge of the hollow portion 221a.

For example, when the pad member 222 has a structure inserted into the hollow portion 221a, the protruding protrusion 222b formed on the upper end of the side portion of the pad member 222 is caught on the upper edge of the hollow portion 221a, thereby allowing the pad member 222 to be stably installed on the piezoelectric element 221.

Furthermore, the vacuum pad 220 may further include an O-ring 230.

The O-ring 230 is installed on a side portion of the pad member 222, thereby maintaining an airtight seal between the pad member 222 and the inner edge of the hollow portion 221a of the piezoelectric element 221.

According to the third embodiment illustrated in FIG. 10, the pad member 222 may be disposed over the circumference of the hollow portion 221a of the piezoelectric element 221.

In addition, the vacuum pad 220 may further include a first elastic member 240.

The first elastic member 240 connects the piezoelectric element 221 and the pad member 222 therebetween.

The first elastic member 240 includes an elastic material, and may thus stably maintain the connection between the pad member 222 and the piezoelectric element 221 even when the pad member 222 is tilted by a warped substrate S.

Furthermore, the first elastic member 240 may have a displacement-absorbing groove 250a formed therein to maintain the connection between the pad member 222 and the piezoelectric element 221 when mechanical displacement of the pad member 222 occurs.

For example, even when the pad member 222 is pushed and moved by the substrate S, the displacement-absorbing groove 250a absorbs the displacement of the pad member 222, so that the first elastic member 240 may stably maintain the connection with the pad member 222.

Furthermore, even when the piezoelectric element 221 expands or contracts, causing rising or falling thereof, thereby changing the position thereof, the displacement-absorbing groove 250a also absorbs the displacement of the piezoelectric element 221, thereby allowing the first elastic member 240 to maintain a stable connection with the piezoelectric element 221. This ultimately allows for an even more stable connection between the pad member 222 and the piezoelectric element 221.

According to the first embodiment illustrated in FIGS. 3 to 8, the second embodiment illustrated in FIG. 9, and the fourth embodiment illustrated in FIG. 11, the piezoelectric element 221 may be disposed around a perimeter of the suction hole 210a in the hand body 210.

Furthermore, according to the first embodiment illustrated in FIGS. 3 to 8 and the second embodiment illustrated in FIG. 9, the vacuum pad 220 may further include a second elastic member 250.

The second elastic member 250 connects the hand body 210 and the piezoelectric element 221 between the hand body 210 and the piezoelectric element 221.

The second elastic member 250 includes an elastic material, and may thus stably maintain the connection between the piezoelectric element 221 and the pad member 222 even when the piezoelectric element 221 undergoes deformation such as expansion or contraction.

Furthermore, the second elastic member 250 may have a displacement-absorbing groove 250a formed therein to maintain the connection with the piezoelectric element 221 when mechanical displacement of the piezoelectric element 221 occurs.

For example, even when the piezoelectric element 221 expands or contracts and rises or falls, thereby changing the position thereof, the displacement-absorbing groove 250a absorbs the displacement of the piezoelectric element 221, allowing the second elastic member 250 to stably maintain the connection with the piezoelectric element 221. This ultimately allows for a more stable connection between the piezoelectric element 221 and the hand body 210.

As set forth above, a vacuum pad, a hand, and a transfer apparatus according to an embodiment may firmly vacuum-absorb even a greatly warped substrate, by configuring a piezoelectric element that receives voltage applied thereto and causes mechanical displacement, in the vacuum pad.

While example embodiments have been illustrated and described above, it will be apparent to those skilled in the art that modifications and variations could be made without departing from the scope of the present disclosure as defined by the appended claims.

What is claimed is:

1. A vacuum pad of a transfer apparatus comprising:
a piezoelectric element installed on a hand body while covering a suction hole of the hand body, and having a hollow portion; and
a pad member installed on the piezoelectric element to cover the hollow portion, and having a pad hole communicating with the suction hole.

2. The vacuum pad of claim 1, wherein the pad member has a donut shape in which the pad hole is formed, and has an outer side portion into which an inner edge of the hollow portion of the piezoelectric element is inserted.

3. The vacuum pad of claim 1, wherein the pad member is inserted into the hollow portion, and
an upper end of a side portion of the pad member is provided with a protruding protrusion formed thereon to be caught on an upper edge of the hollow portion,
wherein the vacuum pad further includes an O-ring installed on a side portion of the pad member to maintain an airtight seal between the pad member and an inner edge of the hollow portion of the piezoelectric element.

4. The vacuum pad of claim 1, wherein the pad member is disposed over a perimeter of the hollow portion of the piezoelectric element,
wherein the vacuum pad further includes a first elastic member connecting the pad member and the piezoelectric element between the pad member and the piezoelectric element,
wherein the first elastic member has a first displacement-absorbing groove formed therein to absorb mechanical displacement of the pad member and the piezoelectric element.

5. The vacuum pad of claim 1, wherein the piezoelectric element is disposed around a perimeter of the suction hole of the hand body,
wherein the vacuum pad further includes a second elastic member connecting the piezoelectric element and the hand body between the piezoelectric element and the hand body,
wherein the second elastic member has a second displacement-absorbing groove formed therein to absorb mechanical displacement of the piezoelectric element.

6. The vacuum pad of claim 1, wherein the piezoelectric element includes a first electrode and a second electrode to which voltages of opposite polarities are applied, and the first electrode or the second electrode is connected to ground.

7. The vacuum pad of claim 1, wherein the piezoelectric element is a bimorph piezoelectric element.

8. A hand of a transfer apparatus comprising:
a hand body having a suction channel in which a suction hole is formed; and
a vacuum pad installed in the suction hole and vacuum-absorbing a substrate,
wherein the vacuum pad includes,
a piezoelectric element installed on the hand body to cover the suction hole and having a hollow portion; and
a pad member installed in the hollow portion of the piezoelectric element and having a pad hole communicating with the suction hole.

9. The hand of claim 8, wherein the pad member has a donut shape with the pad hole formed therein, and has an outer side portion into which an inner edge of the hollow portion of the piezoelectric element is inserted.

10. The hand of claim 8, wherein the pad member is inserted into the hollow portion, and
an upper end of a side portion of the pad member is provided with a protruding protrusion formed thereon to be caught on an upper edge of the hollow portion,
wherein the hand further includes an O-ring installed on a side portion of the pad member to maintain an airtight seal between the pad member and an inner edge of the hollow portion of the piezoelectric element.

11. The hand of claim 8, wherein the pad member is disposed over a perimeter of the hollow portion of the piezoelectric element,
wherein the hand further includes a first elastic member connecting the pad member and the piezoelectric element between the pad member and the piezoelectric element,
wherein the first elastic member has a first displacement-absorbing groove formed therein to absorb mechanical displacement of the pad member and the piezoelectric element.

12. The hand of claim 8, wherein the piezoelectric element is disposed around a perimeter of the suction hole of the hand body,
wherein the hand further includes a second elastic member connecting the piezoelectric element and the hand body between the piezoelectric element and the hand body,
wherein the second elastic member has a second displacement-absorbing groove formed therein to absorb mechanical displacement of the piezoelectric element.

13. The hand of claim 8, wherein the piezoelectric element includes a first electrode and a second electrode to which voltages of opposite polarities are applied, and the first electrode or the second electrode is connected to ground.

14. The hand of claim 8, wherein the piezoelectric element is a bimorph piezoelectric element.

15. A transfer apparatus comprising:
a robot arm;
a hand installed on the robot arm and on which a substrate is mounted; and
a warpage measurement sensor measuring a warpage shape of the substrate and a controller electrically connected to the warpage measurement sensor,
wherein the hand includes,
a hand body installed on the robot arm and having a suction channel with a suction hole formed therein; and
a vacuum pad installed in the suction hole and vacuum-absorbing the substrate,
wherein the vacuum pad includes,
a piezoelectric element installed on the hand body to cover the suction hole and having a hollow portion; and
a pad member installed in the hollow portion of the piezoelectric element and having a pad hole communicating with the suction hole,
wherein the piezoelectric element is a bimorph piezoelectric element, and
the controller controls a voltage applied to the piezoelectric element according to a warpage shape of the substrate measured by the warpage measurement sensor.

16. The transfer apparatus of claim 15, wherein the pad member has a donut shape with the pad hole formed therein, and has an outer side portion into which an inner edge of the hollow portion of the piezoelectric element is inserted.

17. The transfer apparatus of claim 15, wherein the pad member is inserted into the hollow portion, and
an upper end of a side portion of the pad member is provided with a protruding protrusion formed thereon to be caught on an upper edge of the hollow portion,
wherein the transfer apparatus further includes an O-ring installed on a side portion of the pad member to maintain an airtight seal between the pad member and an inner edge of the hollow portion of the piezoelectric element.

18. The transfer apparatus of claim 15, wherein the pad member is disposed over a perimeter of the hollow portion of the piezoelectric element,
wherein the transfer apparatus further includes a first elastic member connecting the pad member and the piezoelectric element between the pad member and the piezoelectric element,
wherein the first elastic member has a first displacement-absorbing groove formed therein to absorb mechanical displacement of the pad member and the piezoelectric element.

19. The transfer apparatus of claim 15, wherein the piezoelectric element is disposed around a perimeter of the suction hole of the hand body,
wherein the transfer apparatus further includes a second elastic member connecting the piezoelectric element and the hand body between the piezoelectric element and the hand body,
wherein the second elastic member has a second displacement-absorbing groove formed therein to absorb mechanical displacement of the piezoelectric element.

20. The transfer apparatus of claim 15, wherein the piezoelectric element includes a first electrode and a second electrode to which voltages of opposite polarities are applied, and the first electrode or the second electrode is connected to ground.
